(19) United States
(12) Patent Application Publication
(10) Pub. No.: US 2025/0234751 A1
(43) Pub. Date: Jul. 17, 2025

(54) DISPLAY SUBSTRATE AND DISPLAY DEVICE

(71) Applicant: BOE TECHNOLOGY GROUP CO., LTD., Beijing (CN)

(72) Inventors: Hao Gao, Beijing (CN); Bingwei Yang, Beijing (CN); Shun Wang, Beijing (CN); Yingqi Yuan, Beijing (CN); Cheng Han, Beijing (CN)

(21) Appl. No.: 18/703,951

(22) PCT Filed: Apr. 18, 2023
(86) PCT No.: PCT/CN2023/088844

§ 371 Date: Apr. 23, 2024

(51) Int. Cl. H10K 59/80

(52) U.S. Cl. CPC H10K 59/873; H10K 59/877; H10K 59/879

(57) ABSTRACT

Provided are a display substrate and a display device. The display substrate includes: a base substrate; a first electrode; a light-emitting layer; a second electrode; an optical extraction layer; a protective layer; an encapsulation layer including a first intercalation layer and a second intercalation layer The color deviation adjustment layer of display substrate is configured to adjust color deviation of display substrate, so that the color deviation has a maximum value at observation angle in range of 0 to 90 degrees. The color deviation adjustment layer includes a first intercalation layer and a second intercalation layer located in the encapsulation layer. The color deviation adjustment layer also includes one of a film layer taken from the encapsulation layer except for the first intercalation layer and the second intercalation layer, the second electrode, the optical extraction layer, and the protective layer. A thickness of the first intercalation layer is less than thickness of the second intercalation layer.

### CROSS-REFERENCE TO RELATED APPLICATION

This application is a Section 371 National Stage Application of International Application No. PCT/CN2023/088844, filed on Apr. 18, 2023, entitled “DISPLAY SUBSTRATE AND DISPLAY DEVICE”, the content of which is hereby incorporated by reference in its entirety.

### TECHNICAL FIELD

The present disclosure relates to a field of display technology, in particular to a display substrate and a display device.

### BACKGROUND

Organic light-emitting diode (OLED) belongs to a current organic light-emitting device, which has advantages of lightweight, wide viewing angle, active light-emitting, continuously adjustable light-emitting color, fast response speed, low energy consumption, simple manufacturing process, high light-emitting efficiency, high brightness and flexible display, and is widely used in various electronic products.

In a manufacturing process of a display device, due to the influence of the manufacturing process, the display device has a certain color deviation, and the color deviation shows different color deviation with the change of an observation angle, which directly affects the display effect of the display device.

### SUMMARY

In order to solve at least one aspect of the above problems, embodiments of the present disclosure provide a display substrate and a display device, which may at least solve the problem of greater changes in the color deviation, thereby improving the display effect of the display device and reducing manufacturing costs.

In an aspect, a display substrate is provided, including: a base substrate; a first electrode located on a side of the base substrate; a light-emitting layer located on a side of the first electrode away from the base substrate; a second electrode located on a side of the light-emitting layer away from the base substrate; an optical extraction layer located on a side of the second electrode away from the base substrate; a protective layer located on a side of the optical extraction layer away from the base substrate; and an encapsulation layer including a first intercalation layer located on a side of the protective layer away from the base substrate and a second intercalation layer located on a side of the first intercalation layer away from the base substrate. The display substrate includes a color deviation adjustment layer configured to adjust a color deviation of the display substrate, so that the color deviation has a maximum value at an observation angle in a range of 0 to 90 degrees. The color deviation adjustment layer includes a first intercalation layer and a second intercalation layer which are located in the encapsulation layer. The color deviation adjustment layer further includes one of a film layer taken from the encapsulation layer except for the first intercalation layer and the second intercalation layer, the second electrode, the optical extraction layer, and the protective layer. The first electrode includes a reflective layer, and the second electrode includes a transparent material. A thickness L₁ of the first intercalation layer is less than a thickness L₂ of the second intercalation layer.

In some exemplary embodiments of the present disclosure, a refractive index n₁ of a material of the first intercalation layer and a refractive index n₂ of a material of the second intercalation layer satisfy 0.6>|n₁−n₂|>0.3.

In some exemplary embodiments of the present disclosure, the color deviation adjustment layer is configured such that a scattered distribution area S₁ of the color deviation of the display substrate at a first observation angle α₁ is greater than a scattered distribution area S₂ of the color deviation of the display substrate at a second observation angle α₂, where 40°<α₁<50°, 0°<α₂<40°, or 50°<α₂<90°.

In some exemplary embodiments of the present disclosure, when 0°<α₂<40°, the scattered distribution area of the color deviation of the display substrate at the second observation angle α₂ is S₂₁. When 50°<α₂<90°, the scattered distribution area of the color deviation of the display substrate at the second observation angle α₂ is S₂₂. A relationship between the S₁, the S₂₁ and the S₂₂ satisfies: S₁>S₂₂>S₂₁.

In some exemplary embodiments of the present disclosure, a ratio of the scattered distribution area S₂₁ of the color deviation of the display substrate at the second observation angle α₂ to the scattered distribution area S₁ of the color deviation of the display substrate at the first observation angle α₁ satisfies: 0.3<S₂₁/S₁<0.55.

In some exemplary embodiments of the present disclosure, a ratio of the scattered distribution area S₂₂ of the color deviation of the display substrate at the second observation angle α₂ to the scattered distribution area S₁ of the color deviation of the display substrate at the first observation angle α₁ satisfies: 0.55<S₂₂/S₁<0.95.

In some exemplary embodiments of the present disclosure, film layers included in the color deviation adjustment layer satisfy:

$$\sum ( {n}_{i} {L}_{i} ) / \sum {L}_{i} = K$$

where n represents a refractive index of a material of each film layer, L represents a thickness of each film layer, i is a positive integer, and K is in a range of 15 to 100.

In some exemplary embodiments of the present disclosure, the encapsulation layer further includes: a first inorganic layer located on a side of the second intercalation layer away from the base substrate; an organic layer located on a side of the first inorganic layer away from the base substrate; and a second inorganic layer located on a side of the organic layer away from the base substrate.

In some exemplary embodiments of the present disclosure, the color deviation adjustment layer includes the first intercalation layer, the second intercalation layer and the first inorganic layer. A refractive index of a material of the first inorganic layer is n₃, and a thickness of the first inorganic layer is L₃. Film layers included in the color deviation adjustment layer satisfy:

$$( {n}_{1} {L}_{1} + {n}_{2} {L}_{2} + {n}_{3} {L}_{3} ) / ( {L}_{1} + {L}_{2} + {L}_{3} ) = K$$

where K is in a range of 40 to 80.

In some exemplary embodiments of the present disclosure, the refractive index n₂ of the material of the second intercalation layer and a refractive index n₃ of a material of the first inorganic layer satisfy 0.5>|n₂−n₃|>0.2.

In some exemplary embodiments of the present disclosure, the color deviation adjustment layer includes the first intercalation layer, the second intercalation layer and the second electrode. A refractive index of a material of the second electrode is n₄, and a thickness of the second electrode is L₄. Film layers included in the color deviation adjustment layer satisfy:

$$( {n}_{1} {L}_{1} + {n}_{2} {L}_{2} + {n}_{4} {L}_{4} ) / ( {L}_{1} + {L}_{2} + {L}_{4} ) = K$$

where K is in a range of 91 to 93.

In some exemplary embodiments of the present disclosure, the refractive index n₁ of the material of the first intercalation layer and the refractive index n₄ of the material of the second electrode satisfy 1.5>|n₁−n₄|>1.

In some exemplary embodiments of the present disclosure, the color deviation adjustment layer includes the first intercalation layer, the second intercalation layer and the protective layer. A refractive index of a material of the protective layer is n₅, and a thickness of the protective layer is L₅. Film layers included in the color deviation adjustment layer satisfy:

$$( {n}_{1} {L}_{1} + {n}_{2} {L}_{2} + {n}_{5} {L}_{5} ) / ( {L}_{1} + {L}_{2} + {L}_{5} ) = K$$

where K is in a range of 16 to 18.

In some exemplary embodiments of the present disclosure, the refractive index n₁ of the material of the first intercalation layer and the refractive index n₅ of the material of the protective layer satisfy 0.5>|n₁−n₅|>0.2.

In some exemplary embodiments of the present disclosure, the color deviation adjustment layer includes the first intercalation layer, the second intercalation layer and the optical extraction layer. A refractive index of a material of the optical extraction layer is n₆, and a thickness of the optical extraction layer is L₆. Film layers included in the color deviation adjustment layer satisfy:

$$( {n}_{1} {L}_{1} + {n}_{2} {L}_{2} + {n}_{6} {L}_{6} ) / ( {L}_{1} + {L}_{2} + {L}_{6} ) = K$$

where K is in a range of 87 to 91.

In some exemplary embodiments of the present disclosure, the refractive index n₁ of the material of the first intercalation layer and the refractive index n₆ of the material of the optical extraction layer satisfy 0.5>|n₁−n₆|>0.2.

In some exemplary embodiments of the present disclosure, the encapsulation layer further includes: a third intercalation layer located between the first inorganic layer and the organic layer.

In some exemplary embodiments of the present disclosure, the color deviation adjustment layer includes the first intercalation layer, the second intercalation layer and the third intercalation layer. A refractive index of a material of the third intercalation layer is n₇, and a thickness of the third intercalation layer is L₇. Film layers included in the color deviation adjustment layer satisfy:

$$( {n}_{1} {L}_{1} + {n}_{2} {L}_{2} + {n}_{7} {L}_{7} ) / ( {L}_{1} + {L}_{2} + {L}_{7} ) = K$$

where K is in a range of 97 to 99.

In some exemplary embodiments of the present disclosure, the refractive index n₂ of the material of the second intercalation layer and the refractive index n₇ of the material of the third intercalation layer satisfy 0.4>|n₂−n₇|>0.1.

In some exemplary embodiments of the present disclosure, the thickness L₇ of the third intercalation layer is in a range of 100 nm to 120 nm.

In some exemplary embodiments of the present disclosure, the light-emitting layer includes a first wavelength light-emitting layer, a second wavelength light-emitting layer and a third wavelength light-emitting layer. A wavelength P₁ of light emitted by the first wavelength light-emitting layer is in a range of 615 nm to 665 nm. A wavelength P₂ of light emitted by the second wavelength light-emitting layer is in a range of 520 nm to 535 nm. A wavelength P₃ of light emitted by the third wavelength light-emitting layer is in a range of 455 nm to 470 nm.

In some exemplary embodiments of the present disclosure, the thickness L₁ of the first intercalation layer is in a range of 65 nm to 95 nm. The thickness L₂ of the second intercalation layer is in a range of 95 nm to 135 nm.

In some exemplary embodiments of the present disclosure, the display substrate further includes: a hole injection layer located between the first electrode and the light-emitting layer; a hole transport layer located on a side of the hole injection layer away from the base substrate; an electron barrier layer located on a side of the hole transport layer away from the base substrate; a hole barrier layer located between the light-emitting layer and the second electrode; an electronic transport layer located on a side of the hole barrier layer away from the base substrate; and an electron injection layer located on a side of the electron transport layer away from the base substrate.

In some exemplary embodiments of the present disclosure, the first electrode includes a non-transparent material, and the second electrode includes a transparent material.

Another aspect of the present disclosure further provides a display device, including the display substrate as described above.

### BRIEF DESCRIPTION OF DRAWINGS

Through the following descriptions of the present disclosure with reference to the accompanying drawings, other objectives and advantages of the present disclosure will become more apparent, and may contribute to a comprehensive understanding of the present disclosure.

FIG. 1 schematically shows a schematic diagram of a scattered distribution of a color deviation of a display substrate used for comparison in the present disclosure;

FIG. 2 schematically shows a schematic top view of a display substrate according to embodiments of the present disclosure;

FIG. 3A schematically shows a schematic cross-sectional view of a structure of a display substrate of an embodiment of the present disclosure;

FIG. 3B schematically shows a schematic diagram of a scattered distribution of a color deviation of the display substrate in FIG. 3A;

FIG. 4A schematically shows a schematic cross-sectional view of a structure of a display substrate of another embodiment of the present disclosure;

FIG. 4B schematically shows a schematic diagram of a scattered distribution of a color deviation of the display substrate in FIG. 4A;

FIG. 5A schematically shows a schematic cross-sectional view of a structure of a display substrate of yet another embodiment of the present disclosure;

FIG. 5B schematically shows a schematic diagram of a scattered distribution of a color deviation of the display substrate in FIG. 5A;

FIG. 6A schematically shows a schematic cross-sectional view of a structure of a display substrate of still another embodiment of the present disclosure;

FIG. 6B schematically shows a schematic diagram of a scattered distribution of a color deviation of the display substrate of FIG. 6A;

FIG. 7A schematically shows a schematic cross-sectional view of a structure of a display substrate of another embodiment of the present disclosure;

FIG. 7B schematically shows a schematic diagram of a scattered distribution of a color deviation of the display substrate in FIG. 7A.

It should be noted that for the sake of clarity, in the accompanying drawings used to describe the embodiments of the present disclosure, dimensions of layers, structures or regions may be enlarged or reduced, that is, these drawings are not drawn according to actual scales.

### DETAILED DESCRIPTION OF EMBODIMENTS

Through embodiments and in conjunction with the accompanying drawings, the technical solution of the present disclosure will be further specifically explained. In the description, the same or similar reference number indicates the same or similar component. The following explanation of the embodiments of the present disclosure with reference to the accompanying drawings is intended to explain the entire inventive concept of the present disclosure, and should not be understood as a limit on the present disclosure.

In addition, in the following detailed description, for the sake of explanation, many specific details are elaborated to provide a comprehensive understanding of the embodiments of the present disclosure. However, it is obvious that one or more embodiments may also be implemented without these specific details.

It should be noted that although the terms “first”, “second”, etc. may be used here to describe various components, members, elements, regions, layers, and/or parts, these components, members, elements, regions, layers, and/or parts should not be limited by these terms. Instead, these terms are used to distinguish one component, member, element, region, layer, and/or part from another component, member, element, region, layer, and/or part. Therefore, for example, the first component, the first member, the first element, the first region, the first layer, and/or the first part discussed below may be referred to as the second component, the second member, the second element, the second region, the second layer, and/or the second part, without departing from the teachings of the present disclosure.

For ease of description, a spatially relational term, e.g., “upper”, “lower”, “left”, “right”, etc. may be used herein to describe a relationship between one element or feature with another element or feature as shown in the drawings. It should be understood that the spatially relational terms are intended to encompass other different orientations of the apparatus in use or operation in addition to an orientation depicted in the drawings. For example, if the apparatus in the drawings is turned over, the elements described as “below” or “beneath” the other elements or features would then be oriented “above” or “on” the other elements or features.

In the present disclosure, the terms “basically”, “about”, “approximately”, “roughly” and other similar terms are used as approximate terms rather than as terms of degree, and they are intended to explain the fixed deviation of measured or calculated values that will be recognized by those of ordinary skill in the art. Taking into account factors such as process fluctuations, measurement problems and errors related to the measurement of a specific amount (i.e., the limitations of the measurement system), the “about” or “approximately” used here includes the stated value, and indicates that the specific value determined by those of ordinary skill in the art is within the acceptable deviation range. For example, “about” may be expressed within one or more standard deviations, or within ±30%, ±20%, ±10%, ±5% of the stated values.

It should be noted that, in this text, the expression “same layer” refers to a layer structure which is formed by forming a layer used to form a specific pattern by the same film-forming process, and then patterning the layer by using the same mask through a one-time patterning process. According to the difference between the specific patterns, the one-time patterning process may include multiple exposures, developments or etching processes, and the specific pattern in the formed layer structure may be continuous or discontinuous. That is, multiple elements, components, structures and/or parts located in the “same layer” are made of the same material and formed by the same composition process. Generally, multiple elements, components, structures and/or parts located in the “same layer” have substantially the same thicknesses.

Those of skill in the art should understand that in this text, unless otherwise defined, the expression of “continuously extending”, “integrated structure”, “entire structure” or similar expressions indicate: a plurality of elements, components, structures and/or parts are located in the same layer, and are formed by the same patterning process in the manufacturing process. There are no intervals or faults between these elements, components, structures and/or parts, but continuously extending structures.

In this text, directional expressions such as “first direction” and “second direction” are used to describe different directions along the pixel region, such as the vertical direction of the pixel region and the horizontal direction of the pixel region. It should be understood that such representation is only an illustrative description, rather than a limit on the present disclosure.

In this text, the term “color deviation” refers to a color difference of the display substrate between a sample and a standard in a color measurement, which may be quantified and represented by a color difference value, such as ΔE, when the ΔE value is larger, the color difference between the sample and the standard is greater, that is, the color deviation is greater. The color deviation of the display substrate changes with the change of an observation angle or measurement angle.

OLED display devices have various pixel construction units, such as full-color display device structures formed by RGB sub-pixels. Organic materials in the OLED display devices are generally manufactured by vapor deposition. As the required sizes of the OLED displays are getting larger and larger, it is not possible to fully ensure that the uniformity of film thicknesses in the vapor deposition process, thereby affecting the performance of monochromatic synthesized white light, while also affecting actual color deviation effects in different regions. For example, when the sizes of the OLED display devices are larger, the display effect differences in the different regions are larger.

In the related art, through an area of a scattered distribution of a plurality of display regions in a certain region of a test sample, these areas are compared with a comparison group, so as to determine a color deviation of the test sample. In a scattered distribution diagram, through the scattered distribution area, a color accuracy and a color deviation of the display may be evaluated. If the scattered distribution area is very small, it means that the color accuracy of the display is very high and the color difference is very small. If the scattered distribution area is very large, it means that there is a large color deviation problem of the display, and the color difference is very large. For example, for an OLED product to be measured, the region to be tested is divided into m×n matrices. According to m×n matrices, m may refer to being arranged in a first direction, and n may refer to being arranged in a second direction perpendicular to the first direction. A test screen may, for example, be a 255 gray scale white screen, and the measurement angle may be 30°, 45°, 60°, etc. For example, by comparing the difference between the test sample and the comparison sample, the color deviation of the test sample may be determined. When testing, the color deviation of the display substrate is determined by comparing the measured data of the pixels on the display substrate at the same perspective. For example, Sₛₚₗᵢₜ may represent an area of the test sample, S_{ref.} may represent an area of a reference sample, and S_{drop} may be understood as the change of Sₛₚₗᵢₜ relative to S_{ref.}. A relationship between Sₛₚₗᵢₜ and S_{ref.} may be represented by an equation:

$${S}_{drop} = ( ( {S}_{split} - {S}_{ref .} ) / {S}_{ref .} ) * 100 \%$$

where S_{drop}=0% is a minimum standard, and S_{drop} is a negative value and may represent that the color deviation phenomenon is improved.

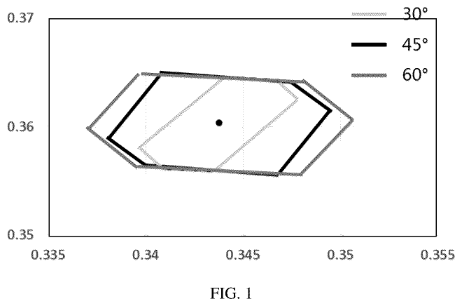

The color deviation in the current display device shows an increasing trend with the change of the observation angle or the measurement angle. FIG. 1 schematically shows a schematic diagram of a scattered distribution of a color deviation of a display substrate used for comparison in the present disclosure. For example, as shown in FIG. 1, when the measurement angle is 30°, the scattered distribution area of the test sample is the smallest. As the measurement angle increases, the scattered distribution area increases. For example, when the measurement angle is 45°, the scattered distribution area of the test sample begins to increase and is larger than the scattered distribution area of the measurement angle of 30°. When the measurement angle is 60°, the scattered distribution area of the test sample is larger than that of all test samples. In this case, when the size of the display device is larger, due to changes of the observation angle or a test angle, the color deviation of different regions shows a large difference, resulting in poor display performance. The size of the display device is larger, resulting in worse display effect of the entire display device. Moreover, the color deviation of the display device increases with the increase of the measurement angle. In order to ensure the display effect of the display device, it is required to improve the maximum color deviation. The related color deviation changes linearly with angles, and may not be quantitatively controlled, which ultimately leads to an increase of product manufacturing costs.

In order to solve the problems described above, embodiments of the present disclosure provide a display substrate, including but not limited to: a base substrate; a first electrode located on a side of the base substrate; a light-emitting layer located on a side of the first electrode away from the base substrate; a second electrode located on a side of the light-emitting layer away from the base substrate; an optical extraction layer located on a side of the second electrode away from the base substrate; a protective layer located on a side of the optical extraction layer away from the base substrate; and an encapsulation layer including a first intercalation layer located on a side of the protective layer away from the base substrate and a second intercalation layer located on a side of the first intercalation layer away from the base substrate. The display substrate includes a color deviation adjustment layer configured to adjust a color deviation of the display substrate, so that the color deviation has a maximum value at an observation angle in a range of 0 to 90 degrees. The color deviation adjustment layer includes a first intercalation layer and a second intercalation layer which are located in the encapsulation layer. The color deviation adjustment layer further includes one of a film layer taken from the encapsulation layer except for the first intercalation layer and the second intercalation layer, and the second electrode, the optical extraction layer, and the protective layer. The first electrode includes a reflective layer, and the second electrode includes a transparent material. A thickness L₁ of the first intercalation layer is less than a thickness L₂ of the second intercalation layer.

According to the embodiments of the present disclosure, through providing a color deviation adjustment layer on the display substrate, the color deviation adjustment layer is respectively taken from a first intercalation layer and a second intercalation layer which are located in the encapsulation layer, and one of a film layer taken from the encapsulation layer except for the first intercalation layer and the second intercalation layer, the second electrode, the optical extraction layer, and the protective layer. That is, the color deviation adjustment layer is configured to include three layers. The color deviation adjustment layer may adjust the color deviation of the display substrate, so that the color deviation may have a maximum value at an observation angle in a range of 0 to 90 degrees. That is, through the color deviation adjustment layer provided in the present disclosure, the color deviation of the display substrate may have a maximum value. When ensuring the display effect of the display substrate, detection and adjustment may be performed only for the measurement angle with the maximum color deviation, which may effectively improve the display effect of the display substrate, At the same time, it may ensure the consistency of the color deviation of the display substrate. For example, the adjustment is performed only for the measurement angle with the maximum color deviation, so that it is possible to ensure the consistency of the color deviation of the display substrate, effectively improve the display effect of the display substrate, and reduce manufacturing costs.

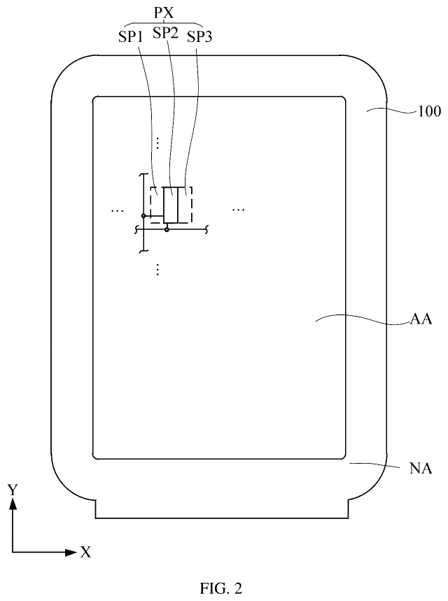

The display substrate of the embodiments of the present disclosure will be specifically described below in combination with FIG. 2 to FIG. 7B.

FIG. 2 schematically shows a schematic top view of a display substrate according to embodiments of the present disclosure. With reference to FIG. 2, the display substrate according to the embodiments of the present disclosure may include a base substrate 10 and a pixel unit PX disposed on the base substrate 10.

The display substrate 100 may include a display region AA and a non-display region NA. The display region AA may be a region provided with a pixel unit PX for displaying an image. Each pixel unit PX will be described later. The non-display region NA is a region where pixel a pixel unit PX is not provided, which may be a region where no image is displayed. The non-display region NA corresponds to the border in the final display device, and a width of the border may be determined according to a width of the non-display region NA.

The display region AA may have various shapes. For example, the display region AA may be provided in various shapes such as a closed polygon including straight edges (such as rectangle), a circle or ellipse, etc. including curved edges, and a semicircle or semi ellipse, etc. including straight edges and curved edges. In the embodiment of the present disclosure, the display region AA is provided as a region with a quadrilateral shape including straight edges. It should be understood that this is only an exemplary embodiment of the present disclosure, rather than a limit on the present disclosure.

The non-display region NA may be disposed on at least one side of the display region AA. In the embodiment of the present disclosure, the non-display region NA may surround a periphery of the display region AA. In the embodiment of the present disclosure, the non-display region NA may include a lateral portion extending in the first direction X and a longitudinal portion extending in the second direction Y.

The pixel unit PX is disposed in the display region AA. The pixel unit PX is the smallest unit used to display images and a plurality of pixel units PX may be provided. For example, the pixel unit PX may include a light-emitting device that emits white light and/or colored light.

A plurality of pixel units PX may be provided and arranged in a matrix form along rows extending in the first direction X and columns extending in the second direction Y. However, the embodiments of the present disclosures do not specifically limit the arrangement form of the pixel units PX, and the pixel units PX may be arranged in various forms. For example, the pixel unit PX may be arranged such that a direction inclined relative to the first direction X and the second direction Y becomes a column direction, and a direction intersecting with the column direction becomes a row direction.

That is to say, the plurality of pixel units PX are arranged in an array along the first direction X and the second direction Y, so as to form a plurality of rows of pixel units and a plurality of columns of pixel units.

A pixel unit PX may include a plurality of sub-pixels. For example, a pixel unit PX may include three sub-pixels, that is, a first sub-pixel SP1, a second sub-pixel SP2 and a third sub-pixel SP3. For example, the first sub-pixel SP1 may be a red sub-pixel, the second sub-pixel SP2 may be a green sub-pixel, and the third sub-pixel SP3 may be a blue sub-pixel.

It should be noted that in the embodiments of the present disclosure, there is no special limitation on the number of sub-pixels included in a pixel unit, and it is not limited to the three mentioned above.

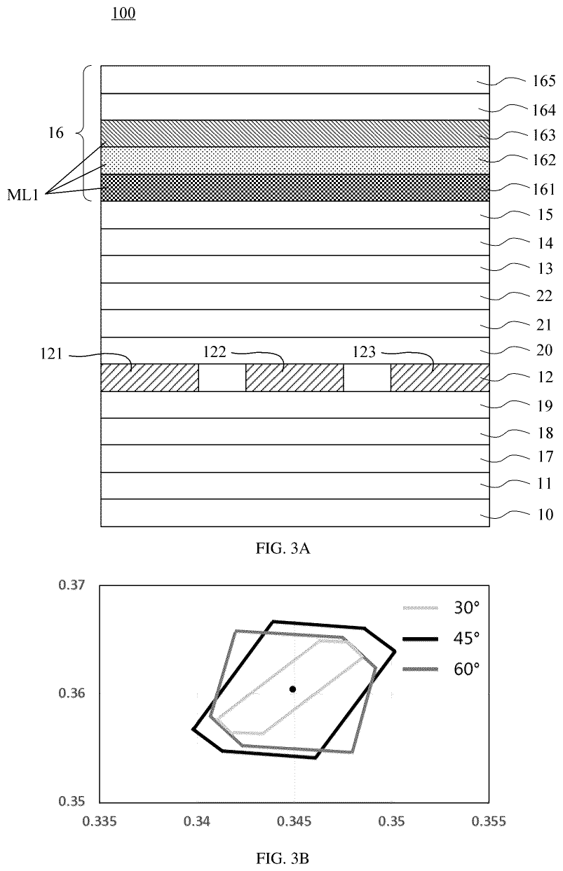

FIG. 3A schematically shows a schematic cross-sectional view of a display substrate of an embodiment of the present disclosure. FIG. 3B schematically shows a schematic diagram of a scattered distribution of a color deviation of the display substrate in FIG. 3A.

FIG. 3A is a schematic cross-sectional view of a structure of the display substrate 100 shown in FIG. 2. As shown in FIG. 3A, the display substrate 100 includes a base substrate 10, a first electrode 11, a light-emitting layer 12, a second electrode 13, an optical extraction layer 14, a protective layer 15 and an encapsulation layer 16. The first electrode 11 is located on a side of the base substrate. The light-emitting layer 12 is located on a side of the first electrode away from the base substrate. The second electrode 13 is located on a side of the light-emitting layer away from the base substrate. The optical extraction layer 14 is located on a side of the second electrode away from the base substrate. The protective layer 15 is located on a side of the optical extraction layer away from the base substrate. The encapsulation layer 16 is located on a side of the protective layer 15 away from the base substrate 10. The encapsulation layer 16 includes a first intercalation layer 161, a second intercalation layer 162, a first inorganic layer 163, an organic layer 164, and a second inorganic layer 165, which are arranged sequentially away from the base substrate 10. Specifically, the first intercalation layer 161 is located on a side of the protective layer 15 away from the base substrate 10. Specifically, the first intercalation layer 161 is located on a side of the protective layer 15 away from the base substrate 10. The second intercalation layer 162 is located on a side of the first intercalation layer away from the base substrate 10. The first inorganic layer 163 is located on a side of the second intercalation layer away from the base substrate. The organic layer 164 is located on a side of the first inorganic layer away from the base substrate. The second inorganic layer 165 is located on a side of the organic layer away from the base substrate.

The display substrate 100 also includes a hole injection layer 17, a hole transport layer 18, an electron barrier layer 19, a hole barrier layer 20, an electron transport layer 21 and an electron injection layer 22. Specifically, the hole injection layer 17 is located between the first electrode and the light-emitting layer. The hole transport layer 18 is located on a side of the hole injection layer away from the base substrate. The electron barrier layer 19 is located on a side of the hole transport layer away from the base substrate. The hole barrier layer 20 is located between the light-emitting layer and the second electrode. The electronic transport layer 21 is located on a side of the hole barrier layer away from the base substrate. The electron injection layer 22 is located on a side of the electron transport layer away from the base substrate.

For example, the base substrate 10 may be made of transparent materials such as glass, polyimide, etc. The first electrode 11 may serve as an anode of the display substrate 100. The first electrode 11 includes a non-transparent material, for example, may include a reflective layer formed by a metal layer, that is, may serve as a conductive electrode or may be used for reflecting light. The first electrode 11 may be a material such as Mg, Ag, etc., or may be an electrode formed by other conductive materials and an emitting layer. For example, the first electrode may also be formed by a conductive material such as ITO, indium zinc oxide, etc. and a reflective layer. The second electrode 13 may include a transparent material. The second electrode may also include Mg/Ag/Al or alloy materials.

The light-emitting layer 12 includes, for example, a first light-emitting layer 121, a second light-emitting layer 122 and a third light-emitting layer 123. The first light-emitting layer 121, the second light-emitting layer 122 and the third light-emitting layer 123 emit spectra of different wavelengths, respectively. For example, the first emitting layer 121 may emit a red spectrum, the second emitting layer 122 may emit a green spectrum, and the third emitting layer 123 may emit a blue spectrum. Specifically, the light-emitting layer may be a structure including R sub-pixel, G sub-pixel and B sub-pixel.

For example, a spectral wavelength of the first light-emitting layer 121 is in a range of 615 nm to 665 nm, a spectral wavelength of the second light-emitting layer 122 is in a range of 520 nm to 535 nm, and a spectral wavelength of the third light-emitting layer 123 is in a range of 455 nm to 470 nm.

In the embodiments of the present disclosure, the display substrate also includes a color deviation adjustment layer ML. The color deviation adjustment layer ML is configured to adjust a color deviation of the display substrate, so that the color deviation of the display substrate 100 has a maximum value at an observation angle or a measurement angle in a range of 0 to 90 degrees

In the display substrate, the fluctuation of a film thickness is greater, so that the impact on the uniformity of the screen display is greater, that is, the scattered distribution area of the color deviation at different points at a fixed observation angle or a fixed measurement angle. For example, when the color deviation of the display substrate of the embodiments of the present disclosure has a maximum value at the observation angle or the measurement angle in a range of 40 degrees to 50 degrees, for example, when the observation angle or the measurement angle is 45 degrees, the color deviation has a maximum value, that is, the scattered distribution area is the largest.

In some embodiments of the present disclosure, the color deviation adjustment layer is configured such that a scattered distribution area S₁ of the color deviation of the display substrate at a first observation angle α₁ is larger than a scattered distribution area S₂ of the color deviation of the display substrate at a second observation angle α₂, where 40°<α₁<50°, 0°<α₂<40°, or 50°<α₂<90°.

When 0°<α₂<40°, the scattered distribution area of the color deviation of the display substrate at the second observation angle α₂ is S₂₁. When 50°<α₂<90°, the scattered distribution area of the color deviation of the display substrate at the second observation angle α₂ is S₂₂. A relationship between S₁, S₂₁ and S₂₂ satisfies: S₁>S₂₂>S₂₁.

In some exemplary embodiments of the present disclosure, a ratio of the scattered distribution area S₂₁ of the color deviation of the display substrate at the second observation angle α₂ to the scattered distribution area S₁ of the color deviation of the display substrate at the first observation angle α₁ satisfies: 0.3<S₂₁/S₁<0.55.

In some exemplary embodiments of the present disclosure, a ratio of the scattered distribution area S₂₂ of the color deviation of the display substrate at the second observation angle α₂ to the scattered distribution area S₁ of the color deviation of the display substrate at the first observation angle α₁ satisfies: 0.55<S₂₂/S₁<0.95.

By providing the color deviation adjustment layer ML, the measurement and adjustment is performed only for the angle of the color deviation at the maximum value in actual manufacturing process of the display substrate, thereby controlling the display effect of the display substrate accurately. For example, the color deviation of the display substrate at the maximum value is reduced, thereby overall reducing the color deviation of the display substrate, improving the display effect of the display substrate. The measurement and adjustment may be performed only for specific angles, thereby reducing the workload of measurement and adjustment, and reducing manufacturing costs. In the embodiments of the present disclosure, the color deviation adjustment layer ML includes a first intercalation layer 161 and a second intercalation layer 162 which are located in the encapsulation layer 16, and another film layer. The another film layer includes one of a film layer taken from the encapsulation layer 16 except for the first intercalation layer 161 and the second intercalation layer 162, the second electrode 13, the optical extraction layer 14, and the protective layer 15.

In the embodiments of the present disclosure, a thickness L₁ of the first intercalation layer 161 in the color deviation adjustment layer ML is less than a thickness L₂ of the second intercalation layer 162. In addition, a refractive index of a material of the first intercalation layer 161 is n₁, and a refractive index of a material of the second intercalation layer is n₂. The n₁ and the n₂ satisfy 0.6>|n₁−n₂|>0.3. For example, the refractive index n₁ of the material of the first intercalation layer 161 may be greater than the refractive index n₂ of the material of the second intercalation layer. Alternatively, the refractive index n₁ of the material of the first intercalation layer 161 may be less than the refractive index n₂ of the material of the second intercalation layer. Therefore, by setting the thicknesses and refractive indexes of the first intercalation layer 161 and the second intercalation layer 162, while setting the thickness and/or refractive index of one film layer of the color deviation adjustment layer ML except for the first intercalation layer 161 and the second intercalation layer 162, so that it is possible to achieve that the color deviation of the display substrate 100 has a maximum value at the observation angle or measurement angle in a range of 0 to 90 degrees by the color deviation adjustment layer ML described above.

In the embodiments of the present disclosure, film layers included in the color deviation adjustment layer ML (such as the first intercalation layer 161, the second intercalation layer 162, and another film layer) satisfy:

$$\sum ( {n}_{i} {L}_{i} ) / \sum {L}_{i} = K$$

where n represents a refractive index of a material of each film layer, L represents that a unit of a thickness of each film layer is nm, i is a positive integer, and K is in a range of 15 to 100. According to differences of a position of another film layer and a refractive index of the another film layer, the value of K changes in the range described above.

In the embodiments of the present disclosure, the thickness L₁ of the first intercalation layer is in a range of 65 nm to 95 nm. The thickness L₂ of the second intercalation layer is in a range of 95 nm to 135 nm.

For example, in the embodiments shown in FIG. 3A and FIG. 3B, the color deviation adjustment layer ML1 includes a first intercalation layer 161, a second intercalation layer 162 and a first inorganic layer 163. Specifically, the first inorganic layer 163 is a film layer in the encapsulation layer 16. A refractive index of a material of the first inorganic layer is n₃, and a thickness of the first inorganic layer is L₃. Film layers included in the color deviation adjustment layer ML1 satisfy:

$$( {n}_{1} {L}_{1} + {n}_{2} {L}_{2} + {n}_{3} {L}_{3} ) / ( {L}_{1} + {L}_{2} + {L}_{3} ) = K$$

where K is in a range of 40 to 80.

In this embodiment, the spectral wavelength of the first light-emitting layer 121 is in a range of 618 nm to 622 nm. The spectral wavelength of the second light-emitting layer 122 is in a range of 524 nm to 533 nm. The spectral wavelength of the third light-emitting layer 123 is in a range of 457 nm to 462 nm.

Specifically, a relationship between the value of K and the spectral wavelength P of the light-emitting layer may be represented by an equation:

$$K = \frac{9 \times {10}^{- 4} \times {P}^{2} - 1.35 \times P + 2420}{1 \times {10}^{- 6} \times {P}^{2} - 0.0015 \times P + 5.7}$$

The refractive index n₂ of the material of the second intercalation layer and a refractive index n₃ of a material of the first inorganic layer satisfy 0.5>|n₂−n₃|>0.2. That is, in this embodiment, n₁ and n₂ satisfy 0.6>|n₁−n₂|>0.3, while n₂ and n₃ satisfy 0.5>|n₂−n₃|>0.2.

In this embodiment, the optical exaction layer 14, the protective layer 15, the first intercalation layer 161 and the second intercalation layer 162 may use inorganic small molecule materials, silicon nitrogen oxides, and other materials.

In this embodiment, the thickness L₁ of the first intercalation layer is, for example, preferably 80 nm, and the thickness L₂ of the second intercalation layer is, for example, preferably 130 nm.

As shown in FIG. 3B, in this embodiment, the scattered distribution of the display substrate is tested at different observation angles or measurement angles, for example, the measurement angles include 30°, 45°, and 60°. As shown in FIG. 3B, the scattered distribution area is smaller at 30° and 60°, while the scattered distribution area is the largest at 45°. A relationship between the scattered distribution areas S at different angles may be represented as: S30°:S45°:S60°=0.33:1:0.93. By setting the thicknesses L and refractive indexes n of the materials of the first intercalation layer 161, the second intercalation layer 162, and the first inorganic layer 163 which are included in the color deviation adjustment layer ML1, the scattered distribution area of the display substrate at 45° is maximized. Therefore, when the color deviation of the display substrate is controlled at 45°, the color deviation at other angles will be controlled at the same time. That is, when controlling the color deviation of the product, only the color deviation at 45° is reduced, while the color deviation of the display substrate at other angles is reduced, which may effectively improve the display effect of the display substrate and reduce manufacturing costs.

According to the embodiments of the present disclosure, by setting the thicknesses and refractive indexes of film layers included in the color deviation adjustment layer of the display substrate, the technical effect of improving color deviation may be achieved, thereby solving the probability of irregular distribution caused by color deviation differences at a plurality of points of the display screen, and overall improving the display and yield of the display substrate.

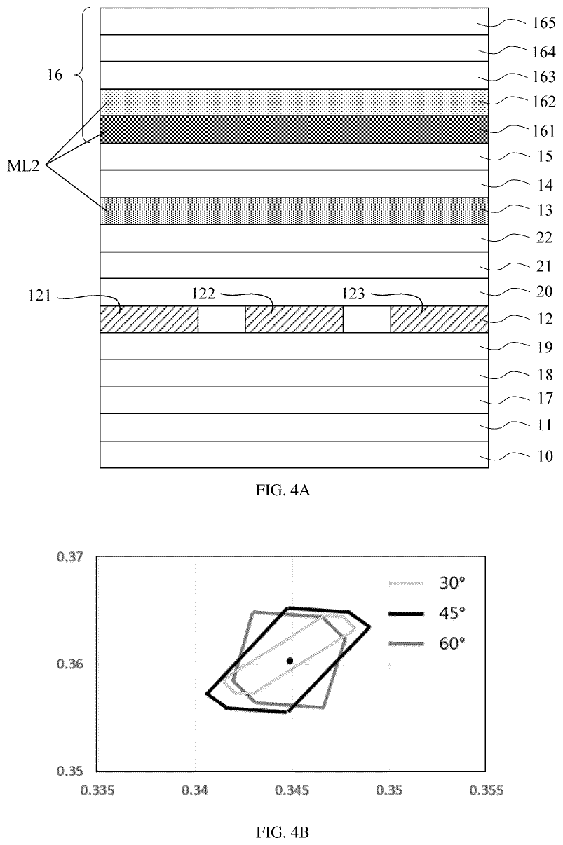

FIG. 4A schematically shows a schematic cross-sectional view of a structure of a display substrate of another embodiment of the present disclosure. FIG. 4B schematically shows a schematic diagram of a scattered distribution of a color deviation of the display substrate in FIG. 4A.

For example, in the embodiments shown in FIG. 4A and FIG. 4B, the color deviation adjustment layer ML2 includes a first intercalation layer 161, a second intercalation layer 162 and a second electrode 13. Specifically, a refractive index of a material of the second electrode 13 is n₄, and a thickness of the second electrode 13 is L₄. Film layers included in the color deviation adjustment layer ML1 satisfy:

$$( {n}_{1} {L}_{1} + {n}_{2} {L}_{2} + {n}_{4} {L}_{4} ) / ( {L}_{1} + {L}_{2} + {L}_{4} ) = K$$

where K is in a range of 91 to 93.

In this embodiment, the spectral wavelength of the first light-emitting layer 121 is in a range of 616 nm to 620 nm. The spectral wavelength of the second light-emitting layer 122 is in a range of 523 nm to 531 nm. The spectral wavelength of the third light-emitting layer 123 is in a range of 456 nm to 461 nm.

Specifically, a relationship between the value of K and the spectral wavelength P of the light-emitting layer may be represented by an equation:

$$K = \frac{3.6 \times {10}^{- 5} \times {P}^{2} - 0.0384 \times P + 340}{3 \times {10}^{- 6} \times {P}^{2} - 0.0032 \times P + 4.4}$$

The refractive index n₁ of the material of the first intercalation layer and the refractive index n₄ of the material of the second electrode satisfy 1.5>|n₁−n₄|>1. In this embodiment, n₁ and n₂ satisfy 0.6>|n₁−n₂|>0.3, while n₁ and n₄ satisfy 1.5>|n₁−n₄|>1.

In this embodiment, the optical extraction layer 14, the protective layer 15, the first intercalation layer 161, and the second intercalation layer 162 may also use inorganic small molecule materials, silicon nitrogen oxides, and other materials.

In this embodiment, the thickness L₁ of the first intercalation layer is, for example, preferably 70 nm. The thickness L₂ of the second intercalation layer is for example, preferably 120 nm.

As shown in FIG. 4B, in this embodiment, the scattered distribution of the display substrate is tested at different observation angles or measurement angles, for example, the measurement angles include 30°, 45°, and 60°. As shown in FIG. 4B, the scattered distribution area is smaller at 300 and 60°, while the scattered distribution area is largest at 45°. A relationship between the scattered distribution area S at different angles may be represented as: S30°:S45°:S60°=0.38:1:0.87. By setting the thicknesses L and refractive indexes n of the materials of the first intercalation layer 161, the second intercalation layer 162, and the second electrode 13 which are included in the color deviation adjustment layer ML2, the scattered distribution area of the display substrate at 45° is maximized. Therefore, when the color deviation of the display substrate is controlled at 45°, the color deviation at other angles will be controlled at the same time. That is, when controlling the color deviation of the product, only the color deviation at 450 is reduced, while the color deviation of the display substrate at other angles is reduced, which may effectively improve the display effect of the display substrate and reduce manufacturing costs.

In this embodiment, when comparing with the scattered distribution area of the comparison sample, S_{drop}=−45%, thus it may be seen that the color deviation has an obvious improvement.

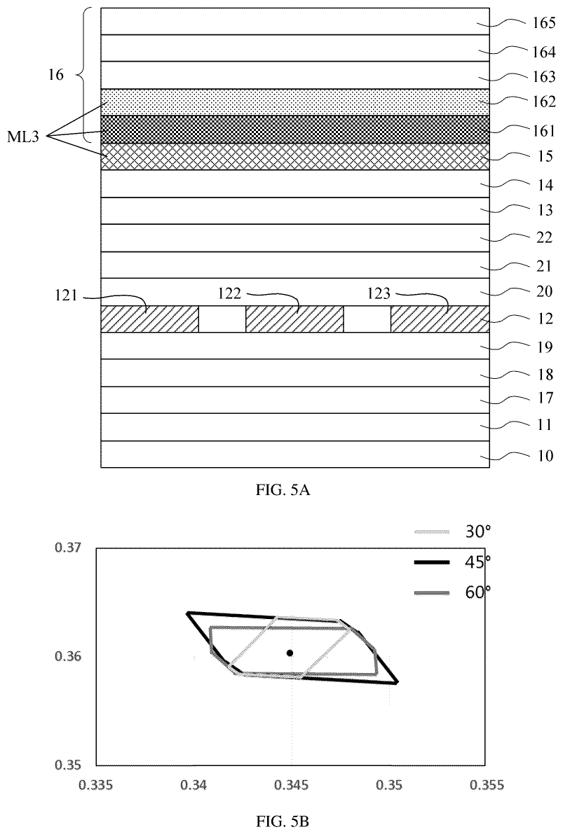

FIG. 5A schematically shows a schematic cross-sectional view of al structure of a display substrate of yet another embodiment of the present disclosure. FIG. 5B schematically shows a schematic diagram of a scattered distribution of a color deviation of the display substrate in FIG. 5A.

For example, in the embodiments shown in FIG. 5A and FIG. 5B, as shown in FIG. 5A, the color deviation adjustment layer ML3 includes a first intercalation layer 161, a second intercalation layer 162 and a protective layer 15. Specifically, a refractive index of a material of the protective layer 15 is n₅, and a thickness of the protective layer 15 is L₅. Film layers included in the color deviation adjustment layer ML3 satisfy:

$$( {n}_{1} {L}_{1} + {n}_{2} {L}_{2} + {n}_{5} {L}_{5} ) / ( {L}_{1} + {L}_{2} + {L}_{5} ) = K$$

where K is in a range of 16 to 18.

In this embodiment, the spectral wavelength of the first light-emitting layer 121 is in a range of 633 nm to 643 nm. The spectral wavelength of the second light-emitting layer 122 is in a range of 524 nm to 530 nm. The spectral wavelength of the third light-emitting layer 123 is in a range of 458 nm to 463 nm.

Specifically, the relationship between the value of K and the spectral wavelength P of the light-emitting layer may be represented by an equation:

$$K = \frac{3.6 \times {10}^{- 7} \times {P}^{2} - 0.006 \times P + 85}{6 \times {10}^{- 8} \times {P}^{2} - 0.0001 \times P + 4.8}$$

The refractive index n₁ of the material of the first intercalation layer and the refractive index n₅ of the material of the protective layer satisfy 0.5>|n₁−n₅>0.2. In this embodiment, n₁ and n₂ satisfy 0.6>|n₁−n₂|>0.3, while n₁ and n₅ satisfy 0.5>|n₁−n₅|>0.2.

In this embodiment, the optical extraction layer 14, the protective layer 15, the first intercalation layer 161, and the second intercalation layer 162 may also use inorganic small molecule materials, silicon nitrogen oxides, and other materials.

In this embodiment, the thickness L1 of the first intercalation layer is, for example, preferably 90 nm. The thickness L2 of the second intercalation layer is for example, preferably 100 nm.

As shown in FIG. 5B, in this embodiment, the scattered distribution of the display substrate is tested at different observation angles or measurement angles, for example, the measurement angles include 30°, 45°, and 60°. As shown in FIG. 5B, the scattered distribution area is smaller at 30° and 60°, while the scattered distribution area is largest at 45°. A relationship between the scattered distribution area S at different angles may be represented as: S30°:S45°:S60°=0.46:1:0.67. By setting the thicknesses L and refractive indexes n of the materials of the first intercalation layer 161, the second intercalation layer 162, and the protective layer 15, which are included in the color deviation adjustment layer ML3, the scattered distribution area of the display substrate at 45° is maximized. Therefore, when the color deviation of the display substrate is controlled at 45°, the color deviation at other angles will be controlled at the same time. That is, when controlling the color deviation of the product, only the color deviation at 450 is reduced, while the color deviation of the display substrate at other angles is reduced, which may effectively improve the display effect of the display substrate and reduce manufacturing costs.

In this embodiment, when comparing with the scattered distribution area of the comparison sample, S_{drop}=−40%, thus it may be seen that the color deviation has an obvious improvement.

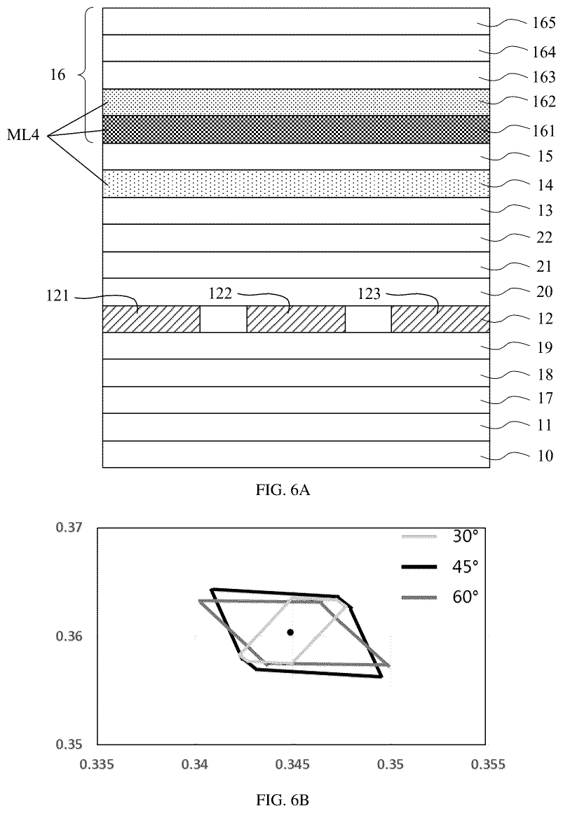

FIG. 6A schematically shows a schematic cross-sectional view of a structure of a display substrate of still another embodiment of the present disclosure. FIG. 6B schematically shows a schematic diagram of a scattered distribution of a color deviation of the display substrate in FIG. 6A.

For example, in the embodiments shown in FIG. 6A and FIG. 6B, as shown in FIG. 6A, the color deviation adjustment layer ML4 includes a first intercalation layer 161, a second intercalation layer 162, and an optical extraction layer 14. Specifically, a refractive index of a material of the optical extraction layer 14 is n₆, and a thickness of the optical extraction layer 14 is L₆. Film layers included in the color deviation adjustment layer ML4 satisfy:

$$( {n}_{1} {L}_{1} + {n}_{2} {L}_{2} + {n}_{6} {L}_{6} ) / ( {L}_{1} + {L}_{2} + {L}_{6} ) = K$$

where K is in a range of 87 to 91.

In this embodiment, the spectral wavelength of the first light-emitting layer 121 is in a range of 650 nm to 661 nm. The spectral wavelength of the second light-emitting layer 122 is in a range of 523 nm to 529 nm. The spectral wavelength of the third light-emitting layer 123 is in a range of 457 nm to 461 nm.

Specifically, a relationship between the value of K and the spectral wavelength P of the light-emitting layer may be represented by an equation:

$$K = \frac{0.0021 \times P + 467.25}{- 0.0003 \times P + 5.4}$$

The refractive index n₁ of the material of the first intercalation layer and a refractive index n₆ of a material of the optical extraction layer satisfy 0.5>|n₁−n₆|>0.2. In this embodiment, n₁ and n₂ satisfy 0.6>|n₁−n₂|>0.3, while n₁ and n₆ satisfy 0.5>|n₁−n₆|>0.2.

In this embodiment, the optical extraction layer 14, the protective layer 15, the first intercalation layer 161, and the second intercalation layer 162 may also use inorganic small molecule materials, silicon nitrogen oxides, and other materials.

In this embodiment, the thickness L₁ of the first intercalation layer is, for example, preferably 70 nm. The thickness L₂ of the second intercalation layer is, for example, preferably 130 nm.

As shown in FIG. 6B, in this embodiment, the scattered distribution of the display substrate is tested at different observation angles or measurement angles, for example, the measurement angles include 30°, 45°, and 60°. As shown in FIG. 6B, the scattered distribution area is smaller at 30° and 60°, while the scattered distribution area is largest at 45°. A relationship between the scattered distribution area S at different angles may be represented as: S30°:S45°:S60°=0.36:1:0.73. By setting the thicknesses L and refractive indexes n of the materials of the first intercalation layer 161, the second intercalation layer 162, and the optical extraction layer 14 which are included in the color deviation adjustment layer ML4, the scattered distribution area of the display substrate at 45° is maximized. Therefore, when the color deviation of the display substrate is controlled at 45°, the color deviation at other angles will be controlled at the same time. That is, when controlling the color deviation of the product, only the color deviation at 45° is reduced, while the color deviation of the display substrate at other angles is reduced, which may effectively improve the display effect of the display substrate and reduce manufacturing costs.

In this embodiment, when comparing with the scattered distribution area of the comparison sample, S_{drop}=−40%, thus it may be seen that the color deviation has an obvious improvement.

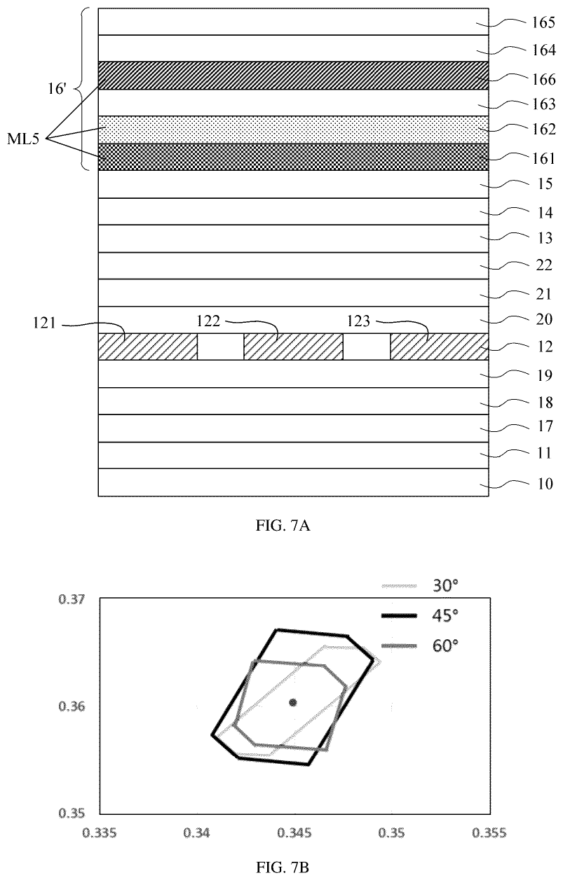

FIG. 7A schematically shows a schematic cross-sectional view of a structure of a display substrate of another embodiment of the present disclosure. FIG. 7B schematically shows a schematic diagram of a scattered distribution of a color deviation of the display substrate in FIG. 7A.

As shown in FIG. 7A and FIG. 7B, in this embodiment, the encapsulation layer 16′ includes a first intercalation layer 161, a second intercalation layer 162, a first inorganic layer 163, a third intercalation layer 166, an organic layer 164 and a second inorganic layer 165 which are arranged sequentially away from the base substrate 10. Specifically, the first intercalation layer 161 is located on a side of the protective layer 15 away from the base substrate 10. The second intercalation layer 162 is located on a side of the first intercalation layer away from the base substrate 10. The first inorganic layer 163 is located on a side of the second intercalation layer away from the base substrate. The third intercalation layer 166 is located on a side of the first inorganic layer 163 away from the base substrate, that is, the third intercalation layer 166 is located between the first inorganic layer 163 and the organic layer 164. The organic layer 164 is located on a side of the third intercalation layer 166 away from the base substrate. The second inorganic layer 165 is located on a side of the organic layer away from the base substrate.

In this embodiment, as shown in FIG. 7A, the color deviation adjustment layer ML5 includes a first intercalation layer 161, a second intercalation layer 162, and a third intercalation layer 166. Specifically, a refractive index of a material of the third intercalation layer 166 is n₇, and a thickness of the third intercalation layer 166 is L₇. Film layers included in the color deviation adjustment layer ML5 satisfy:

$$( {n}_{1} {L}_{1} + {n}_{2} {L}_{2} + {n}_{7} {L}_{7} ) / ( {L}_{1} + {L}_{2} + {L}_{7} ) = K$$

where K is in a range of 97 to 99.

In this embodiment, the spectral wavelength of the first light-emitting layer 121 is in a range of 625 nm to 631 nm. The spectral wavelength of the second light-emitting layer 122 is in a range of 520 nm to 526 nm. The spectral wavelength of the third light-emitting layer 123 is in a range of 458 nm to 466 nm.

Specifically, a relationship between the value of K and the spectral wavelength P of the light-emitting layer may be represented by an equation:

$$K = \frac{4 \times {10}^{- 5} \times {P}^{2} - 0.06 \times P + 51.5}{4 \times {10}^{- 7} \times {P}^{2} - 0.0006 \times P + 5.23}$$

The refractive index n₂ of the material of the second intercalation layer and the refractive index n₇ of the material of the third intercalated satisfy 0.4>|n₂−n₇|>0.1. That is, in this embodiment, n₁ and n₂ satisfy 0.6>|n₁−n₂|>0.3, while n₂ and n₇ satisfy 0.4>|n₂−n₇|>0.1.

In this embodiment, the optical extraction layer 14, the protective layer 15, the first intercalation layer 161, and the second intercalation layer 162 may also use inorganic small molecule materials, silicon nitrogen oxides, and other materials.

In this embodiment, the thickness L₁ of the first intercalation layer is, for example, preferably 80 nm. The thickness L₂ of the second intercalation layer is, for example, preferably 120 nm. The thickness L₇ of the third intercalation layer may be in a range of 100 nm to 120 nm, for example, preferably 110 nm.

As shown in FIG. 7B, in this embodiment, the scattered distribution of the display substrate is tested at different observation angles or measurement angles, for example, the measurement angles include 30°, 45°, and 60°. As shown in FIG. 7B, the scattered distribution area is smaller at 300 and 60°, while the scattered distribution area is largest at 45°. A relationship between the scattered distribution area S at different angles may be represented as: S30°:S45°:S60°=0.54:1:0.59. By setting the thicknesses L and refractive indexes n of the materials of the first intercalation layer 161, the second intercalation layer 162, and the third intercalation layer 166, which are included in the color deviation adjustment layer ML5, the scattered distribution area of the display substrate at 45° is maximized. Therefore, when the color deviation of the display substrate is controlled at 45°, the color deviation at other angles will be controlled at the same time. That is, when controlling the color deviation of the product, only the color deviation at 45° is reduced, while the color deviation of the display substrate at other angles is reduced, which may effectively improve the display effect of the display substrate and reduce manufacturing costs.

In this embodiment, when comparing with the scattered distribution area of the comparison sample, S_{drop}=−18.8%, thus it may be seen that the color deviation has an obvious improvement.

According to the embodiment of the present disclosure, by setting a color deviation adjustment layer on the display substrate, the color deviation adjustment layer may adjust the color deviation of the display substrate, so that the color deviation may have a maximum value at an observation angle in a range of 0 to 90 degrees. That is, by the color deviation adjustment layer provided in the present disclosure, the color deviation of the display substrate has the maximum value. When adjusting the display effect of the display substrate, only the color deviation with the maximum value may be adjusted, thereby reducing steps of detection after the color deviation is adjusted, while significantly improving the display effect of the display substrate. At the same time, it is possible to ensure the consistency of the color deviation of the display substrate and reduce manufacturing costs.

Another aspect of the present disclosure further provides a display device, including the display substrate as described above.

The beneficial effects that may be achieved by the display device in the embodiments of the present disclosure described above are the same as those that may be achieved by the display substrate, which will not be repeated here.

The above display device may be any device that displays images regardless of motion (such as video) or fixed (such as still image), and regardless of texts or images. More specifically, it is contemplated that the embodiments may be implemented in or associated with various electronic devices, such as (but not limited to) mobile phones, wireless devices, personal data assistants (PDAs), handheld or portable computers, GPS receivers/navigators, cameras, MP4 video players, cameras, game consoles, watches, clocks, calculators, TV monitors, flat panel displays, computer monitors, car displays (such as odometer displays, etc.), navigators, cockpit controllers and/or displays, camera view displays (such as rearview camera displays in vehicles), electronic photos, electronic billboards or signs, projectors, building structures, packaging and aesthetic structures (such as a display for an image of a piece of jewelry).

Although some embodiments of the entire concept of the present disclosure have been illustrated and explained, those of ordinary skill in the art will understand that changes may be made to these embodiments without departing from the principles and spirit of the entire invention concept. The scope of the present disclosure is limited by the claims and their equivalents.

1. A display substrate, comprising:
a base substrate;
a first electrode located on a side of the base substrate;
a light-emitting layer located on a side of the first electrode away from the base substrate;
a second electrode located on a side of the light-emitting layer away from the base substrate;
an optical extraction layer located on a side of the second electrode away from the base substrate;
a protective layer located on a side of the optical extraction layer away from the base substrate; and
an encapsulation layer comprising a first intercalation layer located on a side of the protective layer away from the base substrate and a second intercalation layer located on a side of the first intercalation layer away from the base substrate;
wherein the display substrate comprises a color deviation adjustment layer configured to adjust a color deviation of the display substrate, so that the color deviation has a maximum value at an observation angle in a range of 0 to 90 degrees,
wherein the color deviation adjustment layer comprises the first intercalation layer and the second intercalation layer which are located in the encapsulation layer, and the color deviation adjustment layer further comprises one of the group consisting of a film layer taken from the encapsulation layer except for the first intercalation layer and the second intercalation layer, the second electrode, the optical extraction layer, and the protective layer;
wherein the first electrode comprises a reflective layer, and the second electrode comprises a transparent material, and
wherein a thickness L₁ of the first intercalation layer is less than a thickness L₂ of the second intercalation layer.

2. The display substrate of claim 1, wherein a refractive index n₁ of a material of the first intercalation layer and a refractive index n₂ of a material of the second intercalation layer satisfy 0.6>|n₁−n₂|>0.3.

3. The display substrate of claim 2, wherein the color deviation adjustment layer is configured such that a scattered distribution area S₁ of the color deviation of the display substrate at a first observation angle α₁ is greater than a scattered distribution area S₂ of the color deviation of the display substrate at a second observation angle α₂,
$$where \\ 40 ° < {α}_{1} < 50 ° , \\ 0 ° < {α}_{2} < 40 ° , \\ or \\ 50 ° < {α}_{2} < 90 ° .$$

4. The display substrate of claim 3, wherein
when 0°<α₂<40°, the scattered distribution area of the color deviation of the display substrate at the second observation angle α₂ is S₂₁,
when 50°<α₂<90°, the scattered distribution area of the color deviation of the display substrate at the second observation angle α₂ is S₂₂, and
a relationship between S₁, S₂₁ and the S₂₂ satisfies:
$${S}_{1} > {S}_{22} > {S}_{21} .$$

5. The display substrate of claim 4, wherein
a ratio of the scattered distribution area S₂₁ of the color deviation of the display substrate at the second observation angle α₂ to the scattered distribution area S₁ of the color deviation of the display substrate at the first observation angle α₁ satisfies:
$$0.3 < {S}_{21} / {S}_{1} < 0.55 .$$

6. The display substrate of claim 4, wherein
a ratio of the scattered distribution area S₂₂ of the color deviation of the display substrate at the second observation angle α₂ to the scattered distribution area S₁ of the color deviation of the display substrate at the first observation angle α₁ satisfies:
$$0.55 < {S}_{22} / {S}_{1} < 0.95 .$$

7. The display substrate of claim 2, wherein film layers comprised in the color deviation adjustment layer satisfy:
$$\sum ( {n}_{i} {L}_{i} ) / \sum {L}_{i} = K$$
where n represents a refractive index of a material of each film layer, L represents a thickness of each film layer, i is a positive integer, and K is in a range of 15 to 100.

8. The display substrate of claim 7, wherein
the encapsulation layer further comprises:
a first inorganic layer located on a side of the second intercalation layer away from the base substrate;
an organic layer located on a side of the first inorganic layer away from the base substrate;
a second inorganic layer located on a side of the organic layer away from the base substrate.

9. The display substrate of claim 8, wherein
the color deviation adjustment layer comprises the first intercalation layer, the second intercalation layer and the first inorganic layer;
a refractive index of a material of the first inorganic layer is n₃, and a thickness of the first inorganic layer is L₃; and
film layers comprised in the color deviation adjustment layer satisfy:
$$( {n}_{1} {L}_{1} + {n}_{2} {L}_{2} + {n}_{3} {L}_{3} ) / ( {L}_{1} + {L}_{2} + {L}_{3} ) = K$$
where K is in a range of 40 to 80.

10. The display substrate of claim 9, wherein
the refractive index n₂ of the material of the second intercalation layer and a refractive index n₃ of a material of the first inorganic layer satisfy:
$$0.5 > \vert {n}_{2} - {n}_{3} \vert > 0.2 .$$

11. The display substrate of claim 8, wherein
the color deviation adjustment layer comprises the first intercalation layer, the second intercalation layer and the second electrode;
a refractive index of a material of the second electrode is n₄, and a thickness of the second electrode is L₄; and
film layers comprised in the color deviation adjustment layer satisfy:
$$( {n}_{1} {L}_{1} + {n}_{2} {L}_{2} + {n}_{4} {L}_{4} ) / ( {L}_{1} + {L}_{2} + {L}_{4} ) = K$$
where K is in a range of 91 to 93.

12. The display substrate of claim 11, wherein
the refractive index n₁ of the material of the first intercalation layer and the refractive index n₄ of the material of the second electrode satisfy:
$$1.5 > \vert {n}_{1} - {n}_{4} \vert > 1.$$

13. The display substrate of claim 8, wherein
the color deviation adjustment layer comprises the first intercalation layer, the second intercalation layer and the protective layer;
a refractive index of a material of the protective layer is n₅, and a thickness of the protective layer is L₅; and
film layers comprised in the color deviation adjustment layer satisfy:
$$( {n}_{1} {L}_{1} + {n}_{2} {L}_{2} + {n}_{5} {L}_{5} ) / ( {L}_{1} + {L}_{2} + {L}_{5} ) = K$$
where K is in a range of 16 to 18.

14. The display substrate of claim 13, wherein
the refractive index n₁ of the material of the first intercalation layer and the refractive index n₅ of the material of the protective layer satisfy;
$$0.5 > \vert {n}_{1} - {n}_{5} \vert > 0.2.$$

15. The display substrate of claim 8, wherein
the color deviation adjustment layer comprises the first intercalation layer, the second intercalation layer and the optical extraction layer;
a refractive index of a material of the optical extraction layer is n₆, and a thickness of the optical extraction layer is L₆; and
film layers comprised in the color deviation adjustment layer satisfy:
$$( {n}_{1} {L}_{1} + {n}_{2} {L}_{2} + {n}_{6} {L}_{6} ) / ( {L}_{1} + {L}_{2} + {L}_{6} ) = K$$
where K is in a range of 87 to 91.

16. The display substrate of claim 15, wherein
the refractive index n₁ of the material of the first intercalation layer and the refractive index n₆ of the material of the optical extraction layer satisfy:
$$0.5 > \vert {n}_{1} - {n}_{6} \vert > 0.2.$$

17. The display substrate of claim 8, wherein the encapsulation layer further comprises:
a third intercalation layer located between the first inorganic layer and the organic layer.

18. The display substrate of claim 17, wherein
the color deviation adjustment layer comprises the first intercalation layer, the second intercalation layer and the third intercalation layer;
a refractive index of a material of the third intercalation layer is n₇, and a thickness of the third intercalation layer is L₇; and
film layers comprised in the color deviation adjustment layer satisfy:
$$( {n}_{1} {L}_{1} + {n}_{2} {L}_{2} + {n}_{7} {L}_{7} ) / ( {L}_{1} + {L}_{2} + {L}_{7} ) = K$$
where K is in a range of 97 to 99.

19. The display substrate of claim 18, wherein
the refractive index n₂ of the material of the second intercalation layer and the refractive index n₇ of the material of the third intercalation layer satisfy:
$$0.4 > \vert {n}_{2} - {n}_{7} \vert > 0.1 ;$$
the thickness L7 of the third intercalation layer is in a range of 100 nm to 120 nm;
the light-emitting layer comprises a first wavelength light-emitting layer, a second wavelength light-emitting layer and a third wavelength light-emitting layer;
a wavelength P1 of light emitted by the first wavelength light-emitting layer is in a range of 615 nm to 665 nm;
a wavelength P2 of light emitted by the second wavelength light-emitting layer is in a range of 520 nm to 535 nm;
a wavelength P3 of light emitted by the third wavelength light-emitting layer is in a range of 455 nm to 470 nm,
the thickness L1 of the first intercalation layer is in a range of 65 nm to 95 nm; and
the thickness L2 of the second intercalation layer is in a range of 95 nm to 135 nm,
wherein the display substrate further comprises:
a hole injection layer located between the first electrode and the light-emitting layer;
a hole transport layer located on a side of the hole injection layer away from the base substrate:
an electron barrier layer located on a side of the hole transport layer away from the base substrate;
a hole barrier layer located between the light-emitting layer and the second electrode;
an electronic transport layer located on a side of the hole barrier layer away from the base substrate;
an electron injection layer located on a side of the electron transport layer away from the base substrate.

20-23. (canceled)

24. A display device comprising a display substrate of claim 1.
